(19) United States
(12) Patent Application Publication
(10) Pub. No.: US 2019/0032197 A1
(43) Pub. Date: Jan. 31, 2019

(54) CATHODE FOR PLASMA TREATMENT APPARATUS

(71) Applicant: INNOHANCE CO., LTD., Gyeonggi-do (KR)

(72) Inventors: Chan Yong Lee, Seoul (KR); Sang Yong Lee, Gyeonggi-do (KR)

(21) Appl. No.: 16/077,232

(22) PCT Filed: Feb. 17, 2017
(86) PCT No.: PCT/KR2017/001786

§ 371 Date: Aug. 10, 2018

(30) Foreign Application Priority Data
Feb. 17, 2016 (KR) 10-2016-0018317
Oct. 10, 2016 (KR) 10-2016-0130623
Oct. 10, 2016 (KR) 10-2016-0130624

(51) Int. Cl. C23C 14/35; H01J 37/34; H01L 21/285; H05H 1/46

(52) U.S. Cl. CPC C23C 14/35; H05H 1/46; H01L 21/285; H01J 37/3405

(57) ABSTRACT

The present invention relates to a cathode for generating plasma so as to perform predetermined treatment for a material to be treated and, more specifically, to a cathode being capable of generating plasma in all directions in a range of 360° around the cathode. The present invention comprises: an electrode tube which is made from a conductive material and of which the inside is hollow; and a plurality of magnets provided inside the electrode tube, and aligned such that the same poles thereof face each other.

### TECHNICAL FIELD

The present invention relates to a cathode for performing a predetermined treatment on a treated material by generating plasma, and more specifically, to a cathode for a plasma treatment device, capable of generating plasma in all directions in a range of 360 degrees around the cathode.

### BACKGROUND ART

Generally, plasma treatment includes sputtering and PECVD.

The sputtering is a method of tearing off a target material as ions obtained by generating plasma collide with the target material with high energy, which is a technique applied much in practice in the process of an element such as a semiconductor or the like.

A sputtering apparatus is an thin film manufacturing apparatus using capacitive low temperature plasma, which generates plasma by installing two electrodes of ‘+’ and while maintaining an optimum gas pressure, in which ionization easily occurs, in a vacuum container and applying DC or Ac voltage to the electrodes.

In common sense, ‘+’ ions existing in the plasma proceed toward an electrode applied with ‘−’ voltage, and contrarily, ‘−’ ions rush to an electrode applied with ‘+’ voltage.

At this point, since the ‘+’ ions have a large mass and high electrical energy, target materials bounce out when the ‘+’ ions collide with the target surface of ‘−’ electrode, and the torn off target materials are deposited on the facing treated material of ‘+’ electrode.

Contrarily, ‘−’ ions existing in the plasma rush toward the treated material of ‘+’ electrode, not to the target material, and generate a re-sputtering phenomenon of tearing off again the thin film materials that are piled up with difficulty.

If a magnetic field is applied to the generated plasma, a Lorentz's force may be applied to the electrons in the plasma, and a desired plasma density distribution can be obtained according to the arranged form of magnets attached on the back side of a sputter target. This is referred to as magnetron sputtering.

Therefore, the magnetron sputtering has an advantage of preventing re-sputtering and enhancing plasma density.

A sputter cathode of a round disk shape having a diameter of about two to three inches is a most commonly applied form in practice, and the plasma is made and used by creating a uniform magnetic field between two magnetic poles formed by placing a magnetic pole at the center of a rear side of a target and arranging an opposite pole around the magnetic pole.

At this point, etching occurs since etching portions etched on the surface of the target are concentrated in an area of the magnetic field formed to in parallel to the target surface.

Since a general sputter cathode uses only a portion facing a treated material of a target and cannot use the other portions not facing the treated material, utilization of an expensive target is extremely low.

Although an effort of enhancing utilization of a target by rotating (moving) the target to place an unused portion of the target to face the treated material has been made in the prior art to solve the problem, there is a problem in that the processing time is extended since the configuration of an instrument for rotating the target is complicated and the process cannot be performed continuously.

On the other hand, in a chemical vapor deposition (CVD), a thin film of a material formed by chemical actions of source gases is formed on the surface of a treated material by injecting the source gases in a space in which a treated material is arranged to make a conductive film or an insulation film that will be used to form an electronic element or a wire.

A PECVD apparatus is an apparatus for enhancing activities of sources that will form a thin film by generating plasma to enhance efficiency of treatment of a treated material. However, a conventional PECVD apparatus has a problem in that a treatment area of a treated material is also limited since an area in which plasma is generated is limited.

### DISCLOSURE OF INVENTION

### Technical Problem

The present invention has been made to solve the problems described above, and it is an object of the present invention to provide a cathode capable of performing plasma treatment on a treated material by generating plasma in all directions in a range of 360 degrees around the cathode.

Another object of the present invention is to provide a cathode capable of maximizing utilization of a target by reciprocally moving magnets or the target.

Another object of the present invention is to provide a cathode capable of forming a uniform thin film by reciprocally moving magnets of an electrode protection pipe.

### Technical Solution

To accomplish the above objects, according to one aspect of the present invention, there is provided a cathode for a plasma treatment device, the cathode comprising: an electrode pipe formed of a conductive material to have a hollow center; and a plurality of magnets provided inside of the electrode pipe to be arranged to face same poles each other.

In addition, it is preferable that a through hole is formed at a center the magnets, and the magnets arranged to generate a repulsive force against each other are fixed by a magnet fixing shaft passing through the through hole.

In addition, it is preferable that plasma of a donut shape is formed around the magnets.

In addition, it is preferable to further comprise a moving means for moving the magnets to reciprocate, and at this point, it is further preferable that the moving means moves the magnets to reciprocate at a stroke the same as a thickness of the magnet.

According to another aspect of the present invention, there is provided a sputter cathode provided to generate plasma in a sputtering apparatus, the sputter cathode comprising: an electrode pipe formed of a conductive material to have a hollow center; a plurality of magnets provided inside of the electrode pipe to be arranged to face same poles each other; and a target formed of a target material, in which the electrode pipe is installed.

In addition, it is preferable to further comprise a moving means for moving either the magnets or the target to reciprocate to uniformly consume the target.

In addition, it is preferable that a through hole is formed at a center the magnets, and the magnets arranged to generate a repulsive force against each other are fixed by a magnet fixing shaft passing through the through hole.

According to another aspect of the present invention, there is provided a PECVD cathode provided to generate plasma in a PECVD apparatus, the PECVD cathode comprising: an electrode pipe formed of a conductive material to have a hollow center; and a plurality of magnets provided inside of the electrode pipe to be arranged to face same poles each other.

In addition, it is preferable that an electrode protection pipe surrounding an outer circumferential surface of the electrode pipe is provided, or an alumina (Al₂O₃) coating layer is formed on a surface of the electrode pipe.

In addition, it is preferable to further comprise a moving means for moving either the magnets or the electrode protection pipe to form a uniform thin film.

In addition, it is preferable that a through hole is formed at a center the magnets, and the magnets arranged to generate a repulsive force against each other are fixed by a magnet fixing shaft passing through the through hole.

### Advantageous Effects

According to the present invention, plasma of a donut (ring) shape may be generated around a cathode.

Therefore, plasma treatment may be performed in all directions in a range of 360 degrees around the cathode. According thereto, there is an effect in that a plurality of treated materials may be simultaneously treated while being arranged around the cathode in a radial shape, regardless of a shape of the treated materials, and utilization of a target can be maximized in sputtering.

In addition, there is an effect of remarkably increasing surface gauss under the same condition by providing a plurality of magnets in an electrode and arranging the magnets to generate a repulsive force. Like this, there is an advantage of increasing plasma density as the surface gauss increases and, particularly, generating plasma even in a high vacuum atmosphere.

In addition, utilization of a target with respect to a treated material can be maximized and a uniform thin film can be formed by reciprocally moving (scanning) the magnet or the target.

In addition, sputtering and PECVD processes may be sequentially performed in a chamber.

### BRIEF DESCRIPTION OF THE DRAWINGS

FIG. 1 is a view showing the overall configuration of an embodiment according to the present invention.

FIGS. 2 to 6 are views showing a sputter cathode according to the present invention.

FIG. 7 is a vertical cross-sectional view showing a state of a target consumed in a sputter cathode according to the present invention.

FIGS. 8 and 9 are views showing a moving means according to the present invention.

FIG. 10 is a vertical cross-sectional view showing a state of a target consumed in a sputter cathode according to the present invention.

FIG. 11 is a view showing a shutter according to the present invention.

FIGS. 12 to 18 are views showing a PECVD cathode according to the present invention.

### BEST MODE FOR CARRYING OUT THE INVENTION

Hereafter, the configuration and operation of an embodiment according to the present invention will be described in detail, with reference to the accompanying drawings.

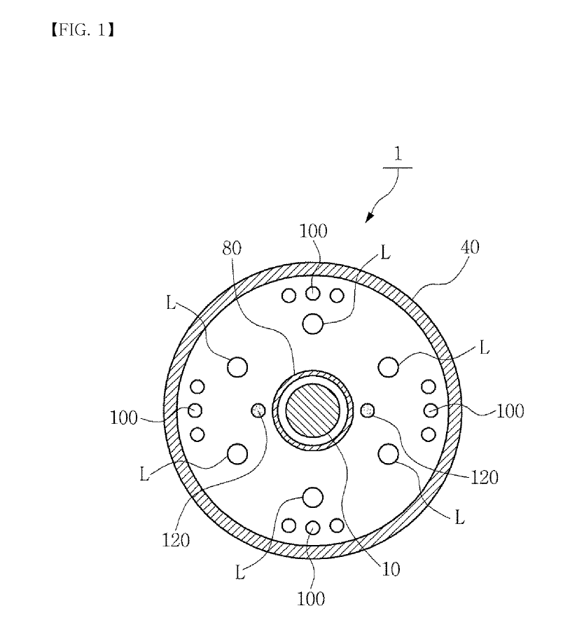

FIG. 1 is a plan view schematically showing the configuration of the present invention. Referring to the figure, an embodiment 1 according to the present invention includes a chamber 40 of a cylindrical shape for providing a space for performing predetermined plasma treatment on a treated material, a sputter cathode 10 provided at the center inside the chamber 40, a shutter 80 for wrapping the sputter cathode 10, and a plurality of PECVD cathodes provided along the edge of the chamber.

The chamber 40 is connected to a vacuum means (not shown) and adjusts a vacuum level according to the process.

As shown in the figure, the sputter cathode 10 is formed in a cylindrical shape as a whole, and the treated materials L are arranged in a radial shape around the sputter cathode 10. A plurality of treated materials L may be placed using a cradle (not shown). The treated materials L may be formed in a variety of shapes and rotated or scanned inside the chamber 40 during the process for uniform treatment.

Particularly, in an embodiment 1 of the present invention, the PECVD cathodes 100 are provided inside the chamber 40 to perform a PECVD process, as well as the sputtering process, inside one chamber 40 on the treated materials L.

The shutter 80 is provided to prevent deposition of a deposition material on the sputter cathode 10 during the PECVD process. The shutter 80 covers the sputter cathode 10 during the PECVD process, and the shutter 80 escapes during the sputtering process.

In addition, although a separate process gas is unnecessary when the surface of the treated material is preprocessed by generating plasma using the PECVD cathode 100, the process gas is needed when an insulation film, a protection film or the like is coated on the surface of the treated material. In this embodiment, a plurality of manifolds 120 are provided inside the chamber 40 to uniformly supply the process gas inside the chamber. The manifolds 20 are formed in a cylindrical shape and has discharge holes formed on the outer circumferential surface to discharge the process gas.

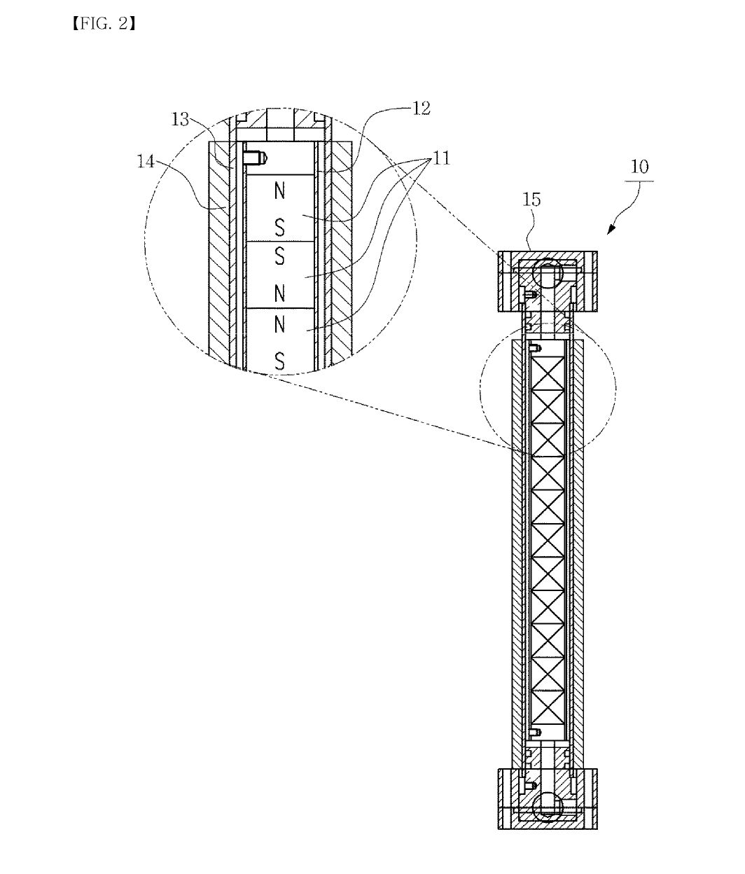

FIG. 2 is a view showing a sputter cathode 10. The sputter cathode 10 includes a plurality of magnets 11, a magnet fixing pipe 12, an electrode pipe 13 and a target 14.

Particularly, according to the present invention, it is understood that the plurality of magnets 11 are installed to face the same poles each other. Accordingly, the magnets are arranged to generate a repulsive force between neighboring magnets when assembly is completed. The magnets are arranged like this to increase surface gauss of the magnets 11. As a result of a measurement, the surface gauss is measured to drastically increase twice or more when the magnets are arranged to face the same poles each other as shown in the embodiment, compared with arranging the magnets 11 to face different poles each other, under the same condition.

If the surface gauss increases like this, it is very advantageous in that plasma density increases, and particularly, plasma can be generated in a high vacuum atmosphere. Since it is very difficult to generate plasma in a high vacuum atmosphere, generating plasma in a high vacuum atmosphere like in the present invention has various advantages. That is, it is well-known that the higher the vacuum level of the chamber atmosphere is in the sputtering, the faster the deposition speed is, and the larger the mean free path is, and thus the thin film is uniformly formed on the treated material, and membranous properties are improved. Accordingly, if the magnets are arranged to face the same poles each other as shown in the present invention, the effects as described above can be expected as plasma is generated in a high vacuum atmosphere.

Since the magnets are arranged to generate a repulsive force in the present invention to increase the surface gauss like this, a magnet fixing means is needed. A magnetic fixing shaft is an example of the magnetic fixing means according to the present invention.

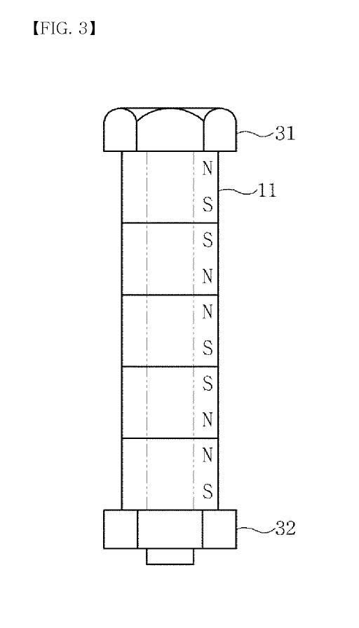

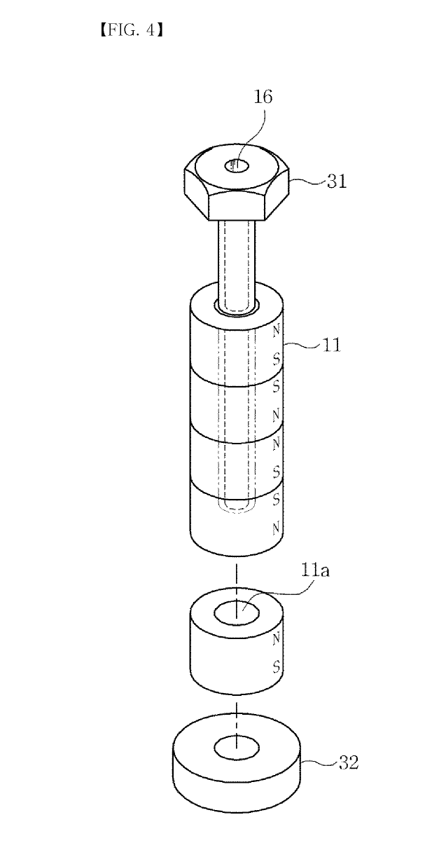

Referring to FIGS. 3 and 4, the magnets 11 are formed in a shape of a cylindrical column, and a through hole 11a is formed at the center thereof, and then a fixing shaft 31 passes through the through hole 11a. Finally, the magnets 11 are arranged and fixed to face the same poles each other by engaging a nut, which is a fastening member 32, at the end of the magnet fixing shaft 31. The magnets 11 can be easily arranged and fixed to face the same poles each other using the magnet fixing shaft 31 and the fastening member 32 like this.

Accordingly, it is natural that a tap is formed at the end of the magnet fixing shaft 31 to engage the fastening member 32, such as a nut or the like. Furthermore, a fluid passage 16 through which a coolant flows may be formed at the center of the magnet fixing shaft 31. In addition, the coolant may be directly supplied to the through hole 11a formed at the center of the magnets, without forming the fluid passage 16 in the magnet fixing shaft 31.

A magnet fixing pipe is another example of the magnet fixing means.

The magnet fixing pipe (12 of FIG. 2) is formed as a pipe of which the top and the bottom are open, and it fixes the magnets to face the same poles each other by sealing the top and the bottom with a cover while a plurality of magnets 11 are inserted therein.

In this embodiment, the electrode pipe 13 is a constitutional component for generating plasma as power is supplied and is formed of a copper or aluminum material.

The target 14 is formed in a cylindrical shape having a hollow center in the axis direction and has the electrode pipe 13 and the magnets 11 inside thereof. Materials are torn off from the target and deposited on the treated material.

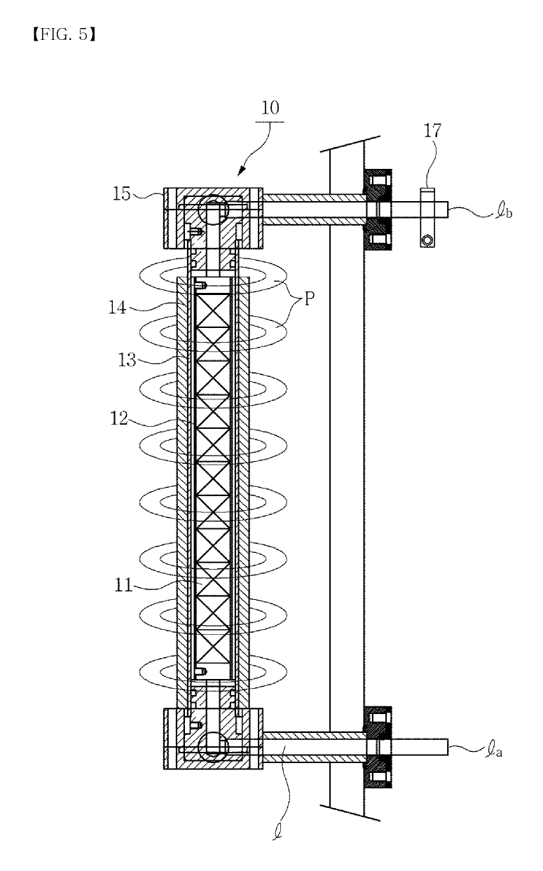

Referring to FIG. 5, a coolant supply hole la and a coolant discharge hole lb for supplying and discharging coolant are formed in upper and lower portions of the sputter cathode 10, and a fluid passage is formed therebetween. The coolant flows through the fluid passage 16 or the through hole 11a formed at the center of the magnet fixing shaft 31. In addition, a power supply 17 is connected.

It is confirmed that plasma P of a donut shape is formed around the magnets 11 when the power 17 is supplied in this state. The plasma P of a donut shape is formed as many as the number of the magnets 11.

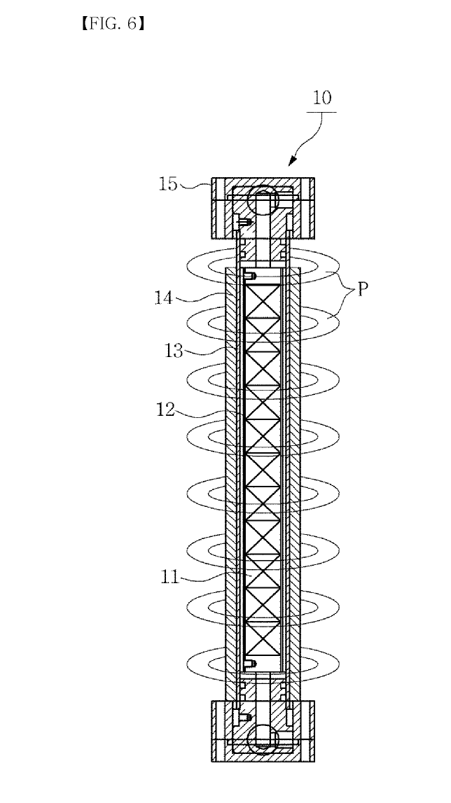

Referring to FIG. 6, it is understood that since the plasma is a ring shape formed three-dimensionally, 360-degree sputtering around the sputter cathode 10 is possible. That is, many treated materials may simultaneously go through the sputtering process by arranging the treated materials in a radial shape around the sputter cathode 10.

In addition, in the case of a treated material of a rectangular shape (e.g., a glass substrate), the sputtering process may be performed on a pair of treated materials at the same time by arranging the treated materials to face each other.

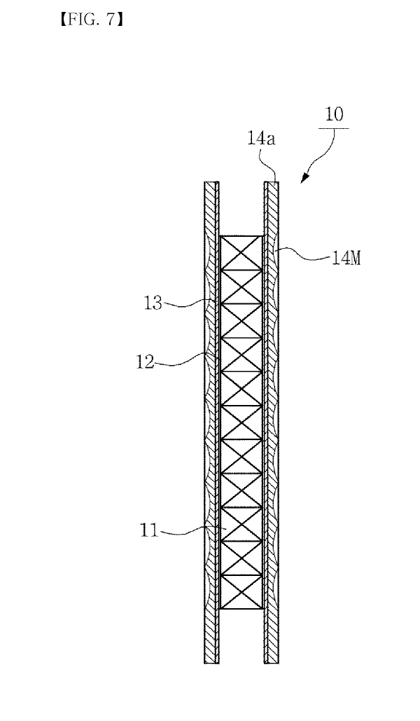

On the other hand, in the present invention, a metal film or the like may be formed on the surface of a treated material through sputtering by generating plasma of a ring shape around the magnets, and the plasma of a ring shape is generated as many as the number of magnets. If the sputtering process is performed like this, the target 14a is not consumed uniformly, but consumed while making a waveform of a ripple shape on the vertical cross section (see FIG. 7). That is, a plurality of grooves 14M are formed on the target in the circumference direction at regular intervals. This is since that plasma of a ring shape is formed as many as the magnets, and the target is intensively consumed at the positions where the plasma is formed.

The present invention provides a moving means considering this phenomenon.

The moving means is a constitutional component for moving either the magnets or the target to reciprocate while the other one is fixed.

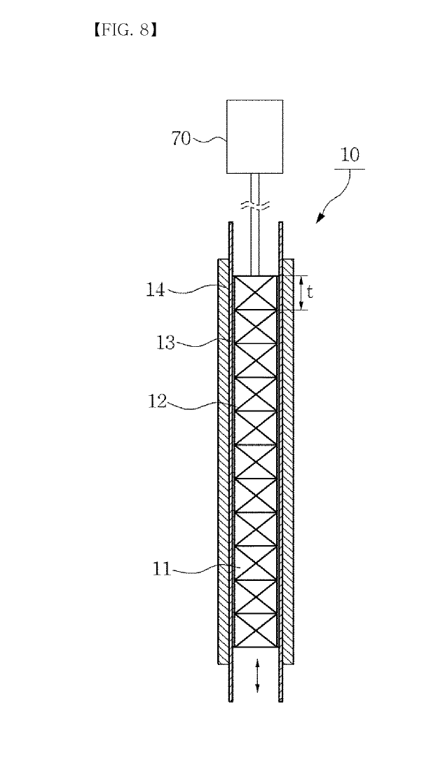

Referring to FIG. 8, in an embodiment of the moving means 70 according to the present invention, the magnets 11 are moved to reciprocate up and down while the target 14 is fixed. The moving stroke of the magnets by the moving means 70 is the thickness t of a magnet. That is, the moving means 70 moves the magnets to reciprocate up and down as much as a distance corresponding to the thickness t of a magnet.

The moving means 70 is a publicized driving means such as a motor, an air cylinder or the like and constantly moves the magnets 11 to reciprocate up and down during the deposition process.

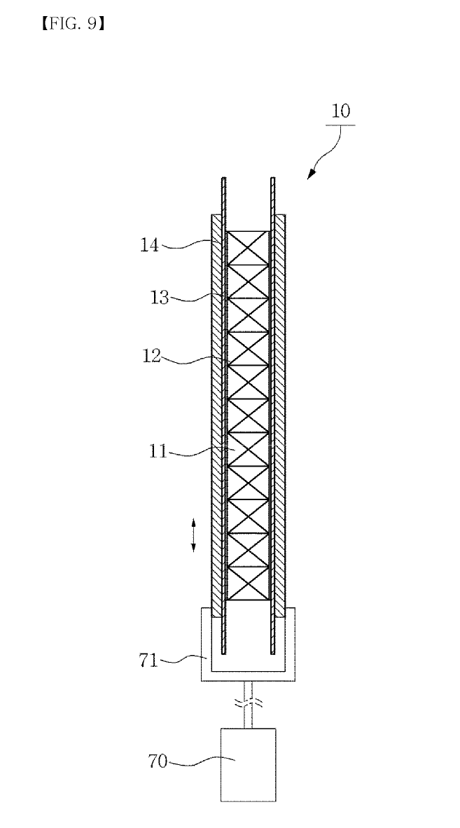

FIG. 9 is a view showing another embodiment of the moving means 70 according to the present invention. As shown in the figure, the moving means 70 moves the target 14 to constantly reciprocate up and down while the magnet 11 is fixed. To this end, a jig 71 holding the target 14 and connected to the moving means 70 is provided.

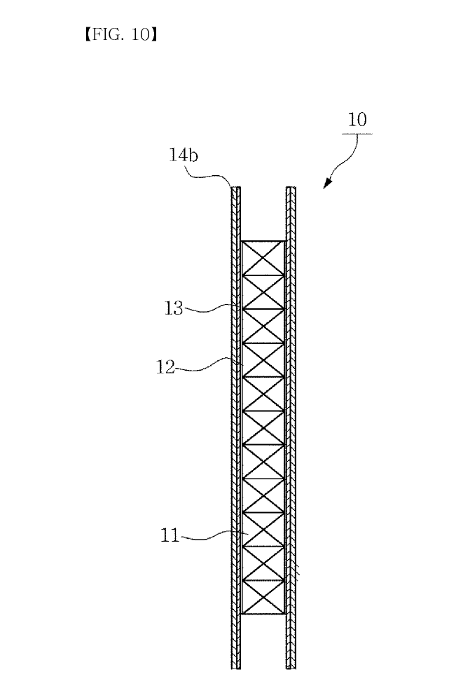

If the magnets 11 or the target 14 is scanned during the sputtering like this, the target (see 14b of FIG. 10) is uniformly consumed across the entire range and can be evenly used, and therefore, utilization of the expensive target remarkably increases (see FIG. 10).

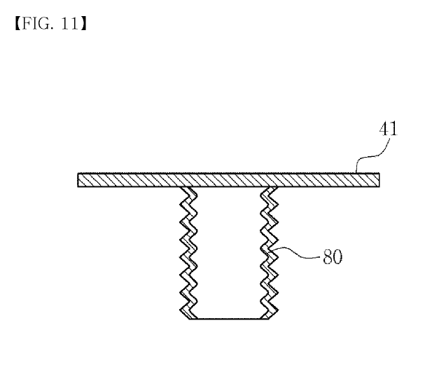

FIG. 11 is a view showing the shutter 80. The shutter 80 prevents deposition of a deposition material on the sputter cathode 10, particularly, the target 14, during a PECVD process. Specifically, the shutter 80 is configured in the form of bellows fixed to a lead 41 formed on the top of the chamber 40 and expanding and contracting in the vertical direction. Therefore, the shutter 80 expands during the CVD process to wrap the sputter cathode 10 and prevent contamination, and the shutter 80 contracts to rise during the sputtering process to open the sputter cathode 10.

An embodiment of the present invention further includes a PECVD cathode for deposition on a treated material inside the chamber (see FIG. 1).

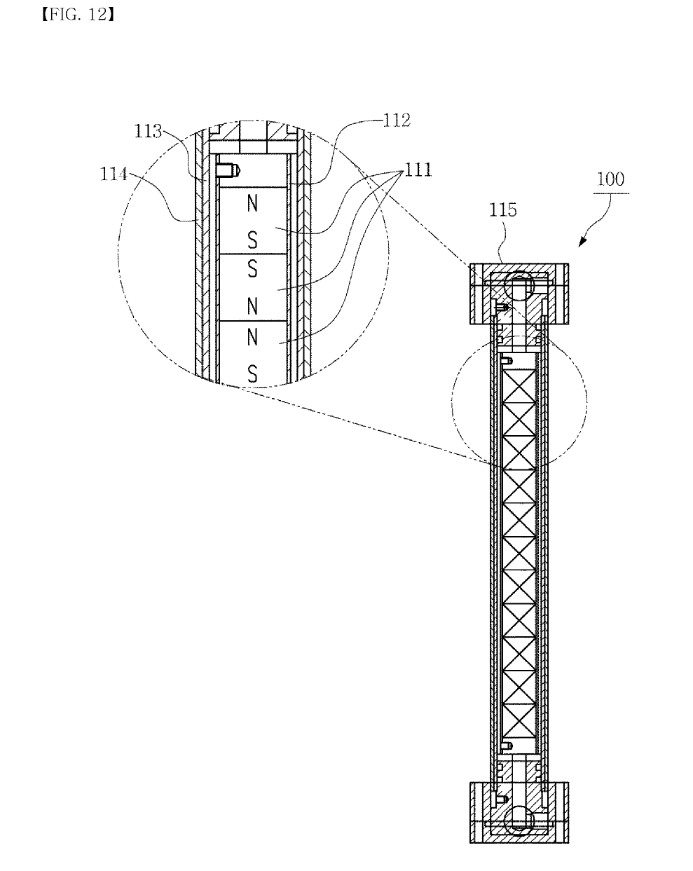

FIG. 12 is a view showing a PECVD cathode. The PECVD cathode 100 includes magnets 111, a magnet fixing pipe 112, an electrode pipe 113 and an electrode protection pipe. In this embodiment, a quartz pipe 114 is provided as the electrode protection pipe.

Particularly, according to the present invention, it is understood that the plurality of magnets 111 are installed to face the same poles each other. Accordingly, the magnets are arranged to generate a repulsive force between neighboring magnets when assembly is completed. The magnets are arranged like this to increase surface gauss of the magnets 111. Accordingly, since the deposition speed and the mean free path increase, the thin film is uniformly formed on the treated material, and membranous properties are improved.

Since the magnets are arranged to generate a repulsive force in the present invention to increase the surface gauss like this, a magnet fixing means is needed. A magnetic fixing shaft is an example of the magnetic fixing means according to the present invention.

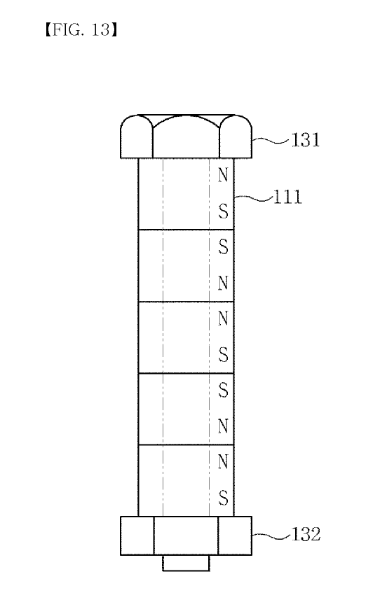

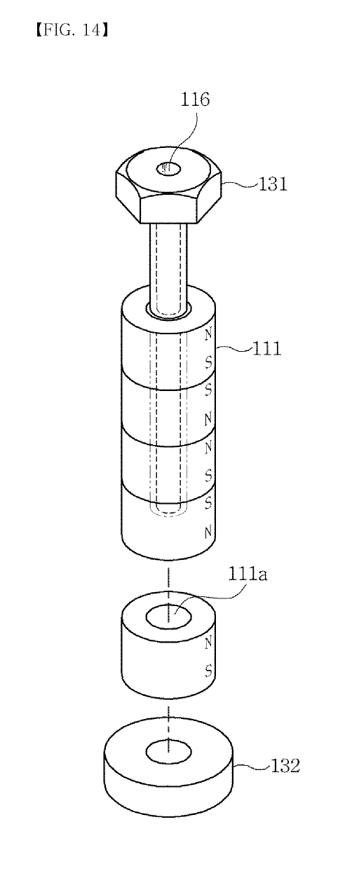

Referring to FIGS. 13 and 14, the magnets 111 are formed in a shape of a cylindrical column, a through hole 111a is formed at the center thereof, and a fixing shaft 131 passes through the through hole 111a. Finally, the magnets 111 are arranged and fixed to face the same poles each other by engaging a nut, which is a fastening member 132, at an end of the magnet fixing shaft 131. The magnets 111 can be easily arranged and fixed to face the same poles each other using the magnet fixing shaft 131 and the fastening member 132 like this.

Accordingly, it is natural that a tap is formed at an end of the magnet fixing shaft 131 to engage the fastening member 132. Furthermore, a fluid passage 116 through which a coolant flows may be formed at the center of the magnet fixing shaft 131.

A magnet fixing pipe is another example of the magnet fixing means.

In this embodiment, the electrode pipe 113 is a constitutional component for generating plasma as power is supplied and is formed of a copper or aluminum material.

On the other hand, if the PECVD process is performed on a treated material L by generating plasma inside the chamber, a material is attached on the surface of the electrode pipe 113. Therefore, the electrode pipe 113 should be cleaned periodically. Accordingly, the quartz pipe 114 is manufactured to cover the outer side of the electrode pipe 113, which is a constitutional component for protecting the electrode as foreign materials adhere to the quartz pipe 114 instead of the electrode pipe 113. Of course, a configuration excluding the quartz pipe 114 is also possible, and particularly, the problem of adhering foreign materials can be solved by performing an anodizing treatment on the surface of the electrode pipe 113 instead of the quartz pipe 114.

In addition, particles may be generated as the film is not adhered, but torn off, as the surface of the quartz pipe 114 is slippery. To prevent this phenomenon, it may be considered to remove the quartz pipe 114 and form an alumina (Al₂O₃) coating layer on the surface of the electrode pipe 113. That is, if the alumina (Al₂O₃) coating layer is formed on the surface of the electrode pipe 113 of a copper material, the adhered film is not torn off during the process since the surface of the electrode pipe becomes coarse, and thus the particles are not generated.

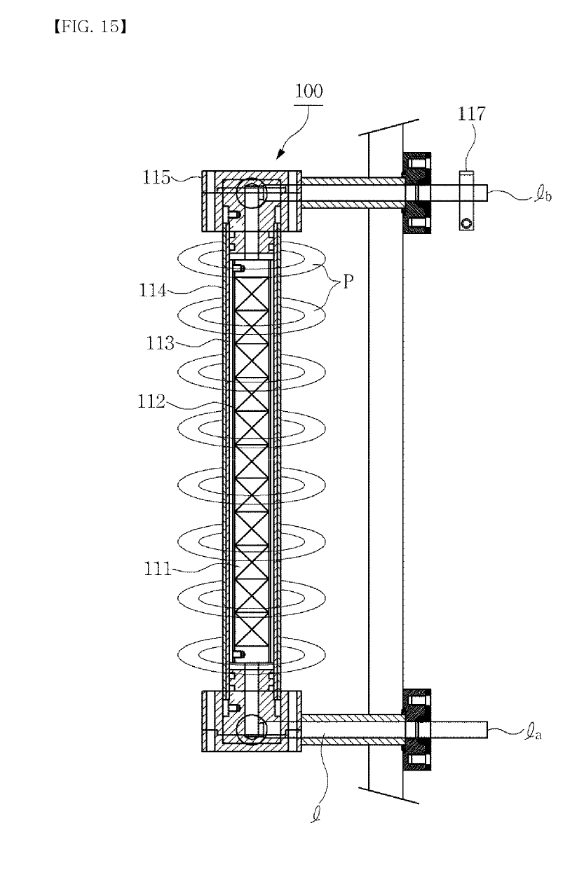

Referring to FIG. 15, a coolant supply hole la and a coolant discharge hole lb for supplying and discharging coolant are formed in upper and lower portions of the PECVD cathode 100, and a fluid passage is formed therebetween. The coolant flows through the fluid passage 116 or the through hole 111a formed at the center of the magnet fixing shaft 131. In addition, a power supply 117 is connected.

It is confirmed that plasma P of a donut shape is formed around the magnets 111 when the power 117 is supplied in this state. The plasma P of a ring shape is formed as many as the number of the magnets 111.

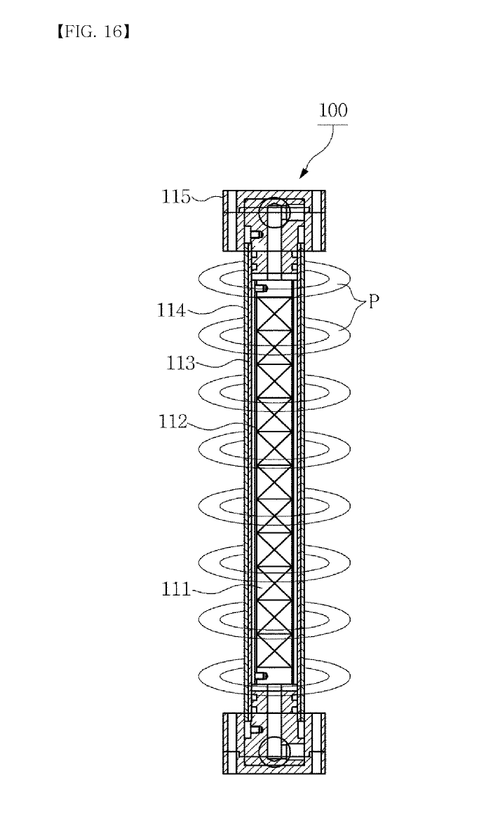

Referring to FIG. 16, it is understood that since the plasma is a ring shape formed three-dimensionally, a 360-degree PECVD process around the PECVD cathode 110 is possible. That is, many treated materials may simultaneously go through the PECVD process by arranging the treated materials in a radial shape around the PECVD cathode 110.

In addition, in the case of a treated material of a rectangular shape (e.g., a glass substrate), the PECVD process may be performed on a pair of treated materials at the same time by arranging the treated materials to face each other.

On the other hand, in the present invention, an insulation film, a protection film or the like may be formed on the surface of a treated material through PECVD process by generating plasma of a ring shape around the magnets, and the plasma of a ring shape is generated as many as the number of magnets. If the PECVD process is performed like this, a material is also deposited on the outer circumferential surface of the quartz pipe 114, and this can be a problem. In an embodiment without the quartz pipe 114, a film of a material is deposited on the outer circumferential surface of the electrode pipe 113. Particularly, since the deposition material is not uniformly deposited on the quartz pipe 114 or the electrode pipe 113, but thickly deposited on some sections by the plasma P of a ring shape, a film having a cross section of a ripple shape is formed on the quartz pipe 114. Depositing a deposition material on the quartz pipe 114 is a problem, and moreover, it is a further greater problem to deposit a deposition material not in a uniform thickness, but to have a cross section of a ripple shape (waveform). In this case, it is since deposition on the treated material is uneven. The deposition material is deposited more thickly at the center portion of the magnets, and thus the cross section is shaped in a waveform.

The present invention provides a moving means considering this phenomenon.

The moving means is a constitutional component for moving the magnets to reciprocate.

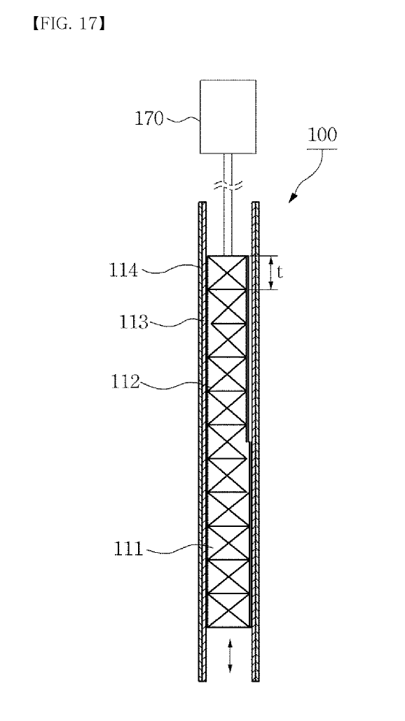

Referring to FIG. 17, in an embodiment of the moving means 170 according to the present invention, the magnets 111 is scanned up and down while the quartz pipe 114 is fixed. That is, the moving means 170 is a publicized driving means, such as a motor, an air cylinder or the like, and constantly moves the magnets to reciprocate up and down during the deposition process.

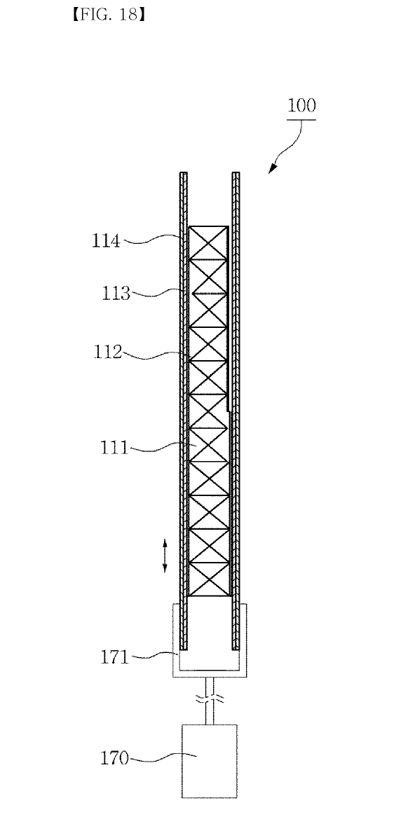

FIG. 18 is a view showing another embodiment of the moving means 170 according to the present invention. As shown in the figure, the moving means 170 moves the quartz pipe 114 to constantly reciprocate up and down while the magnet 111 is fixed. To this end, a jig 171 holding the quartz pipe 114 and connected to the moving means 170 is provided.

When the moving means 170 moves the magnets 111 or the quartz pipe 114 to reciprocate, the stroke of the reciprocating movement is as much as a length corresponding to the thickness of a magnet 111.

If the magnets 111 or the quartz pipe 114 reciprocates during the PECVD process like this, a deposition material is deposited on the quartz pipe 114 at a uniform thickness although it is deposited. Accordingly, uniformity is improved in the plasma treatment of the treated material.

Hereinafter, the operation state of an embodiment according to the present invention will be described.

Referring to FIG. 1, a treated material L is loaded inside the chamber 40. As shown in the figure, the treated material L is arranged in a radial shape around the sputter cathode 10.

In this state, first, the surface of the treated material is preprocessed by generating plasma using the PECVD cathode 100. A process gas is unnecessary in preprocessing.

Next, the sputter cathode 10 is opened by escaping the shutter 80, and a metal film is sputtered on the surface of the treated material L using the sputter cathode 10.

Next, the sputter cathode 10 is covered using the shutter 80, and a protection film is formed on the metal film using the PECVD cathode 100. At this point, the magnets 111 or the quartz pipe 114 is scanned up and down using a moving means (170 of FIGS. 17 and 18). In addition, it is natural that the manifold 120 supplies a predetermined process gas at this point.

That is, in the present invention, 360-degree sputtering around the sputter cathode 10 is possible, and in addition, the PECVD process and the sputtering process can be sequentially performed in a chamber.

Particularly, the present invention may remarkably increase surface gauss by arranging the magnets 11 or 111 of the sputter cathode 10 or the PECVD cathode 100 to face the same poles each other, thereby increasing the plasma density, and particularly, the plasma can be generated even in a high vacuum atmosphere.

Alternatively, an embodiment according to the present invention may be used as another process.

For example, after loading a treated material L inside the chamber, a protection film is formed by generating plasma on the surface of the treated material L using the PECVD cathode 100. At this point, the manifold 120 supplies a predetermined process gas. In addition, the sputter cathode 10 is covered using the shutter 80 to prevent deposition of a deposition material on the sputter cathode 10.

Next, the sputter cathode 10 is opened by contracting (raising) the shutter 80, and a metal film is sputtered on the protection film using the sputter cathode 10.

Next, the process may be performed in order of covering the sputter cathode 10 using the shutter 80 and forming a protection film on the metal film using the PECVD cathode 100.

Although it is described in the embodiment that the sputter cathode 10 covered and all the PECVD cathodes 100 are provided inside the chamber, alternatively, only the sputter cathode 10 or the PECVD cathode 100 may be provided inside the chamber. Since plasma is formed in a donut shape in either case, the plasma treatment can be performed in all directions in a range of 360 degrees.

### INDUSTRIAL APPLICABILITY

The present invention may be used in the industry in a variety of forms such as forming a thin film, coating and the like by generating plasma in a sputtering apparatus or a PECVD apparatus.

1. A cathode for a plasma treatment device, the cathode comprising:
an electrode pipe formed of a conductive material to have a hollow center; and
a plurality of magnets provided inside of the electrode pipe to be arranged to face same poles each other.

2. The cathode according to claim 1, wherein a through hole is formed at a center the magnets, and the magnets arranged to generate a repulsive force against each other are fixed by a magnet fixing shaft passing through the through hole.

3. The cathode according to claim 1, wherein plasma of a donut shape is formed around the magnets.

4. The cathode according to claim 1, further comprising a moving means for moving the magnets to reciprocate.

5. The cathode according to claim 4, wherein the moving means moves the magnets to reciprocate at a stroke the same as a thickness of the magnet.

6. A sputter cathode provided to generate plasma in a sputtering apparatus, the sputter cathode comprising:
an electrode pipe formed of a conductive material to have a hollow center;
a plurality of magnets provided inside of the electrode pipe to be arranged to face same poles each other; and
a target formed of a target material, in which the electrode pipe is installed.

7. The sputter cathode according to claim 6, further comprising a moving means for moving either the magnets or the target to reciprocate to uniformly consume the target.

8. The sputter cathode according to claim 6, wherein a through hole is formed at a center the magnets, and the magnets arranged to generate a repulsive force against each other are fixed by a magnet fixing shaft passing through the through hole.

9. A PECVD cathode provided to generate plasma in a PECVD apparatus, the PECVD cathode comprising:
an electrode pipe formed of a conductive material to have a hollow center; and
a plurality of magnets provided inside of the electrode pipe to be arranged to face same poles each other.

10. The PECVD cathode according to claim 9, wherein an electrode protection pipe surrounding an outer circumferential surface of the electrode pipe is provided.

11. The PECVD cathode according to claim 10, further comprising a moving means for moving either the magnets or the electrode protection pipe to form a uniform thin film.

12. The PECVD cathode according to claim 9, wherein an alumina (Al₂O₃) coating layer is formed on a surface of the electrode pipe.

13. The PECVD cathode according to claim 9, wherein a through hole is formed at a center the magnets, and the magnets arranged to generate a repulsive force against each other are fixed by a magnet fixing shaft passing through the through hole.
